(19) United States
(12) Patent Application Publication
(10) Pub. No.: US 2008/0156575 A1
(43) Pub. Date: Jul. 3, 2008

(54) Portable speaker enclosure

(76) Inventor: Jason Entner, Brooklyn, NY (US)

Correspondence Address: COOPER & DUNHAM, LLP, 1185 AVENUE OF THE AMERICAS, NEW YORK, NY, 10036, US

(21) Appl. No.: 11/649,698

(22) Filed: Jan. 3, 2007

(51) Int. Cl. H05K 5/03

(52) U.S. Cl. 181/148

(57) ABSTRACT

This invention provides an enclosure for a speaker, wherein the enclosure comprises a means for attachment to an article of luggage, and wherein the enclosure is (i) composed of a suitable acoustic material and (ii) is flexible. This invention further provides a carrying case comprising a manually removable enclosure for a speaker, which enclosure comprises a means for attachment to the carrying case and is (i) composed of a suitable acoustic material and (ii) is flexible.

### BACKGROUND OF THE INVENTION

This invention relates generally to the field of enclosures for devices capable of emitting audio signals. More, particularly, this invention relates to an enclosure for a speaker, wherein the enclosure comprises a means for attachment to an article of luggage, and wherein the enclosure is (i) composed of a suitable acoustic material and (ii) is flexible. This invention further provides a carrying case comprising a manually removable enclosure for a speaker, which enclosure comprises a means for attachment to the carrying case and is (i) composed of a suitable acoustic material and (ii) is flexible.

With the proliferation of personal audio players (e.g. MP3 players) in today's society, the need arises for a speaker system that is both portable and able to produce a high quality audio output.

The present invention is an enclosure for a speaker that is capable of being attached to an article of luggage and rigid enough to produce a high quality audio output, yet flexible enough to withstand physical damage.

### SUMMARY OF THE INVENTION

This invention provides an enclosure for a speaker, wherein the enclosure comprises a means for attachment to an article of luggage, and wherein the enclosure is (i) composed of a suitable acoustic material and (ii) is flexible.

This invention further provides a carrying case comprising a manually removable enclosure for a speaker, which enclosure comprises a means for attachment to the carrying case and is (i) composed of a suitable acoustic material and (ii) is flexible.

The advantages and features of the invention will become apparent to those skilled in the art upon consideration of the following description of the invention. The invention may be best understood by reference to the following description.

### BRIEF DESCRIPTION OF THE FIGURES

FIG. 1

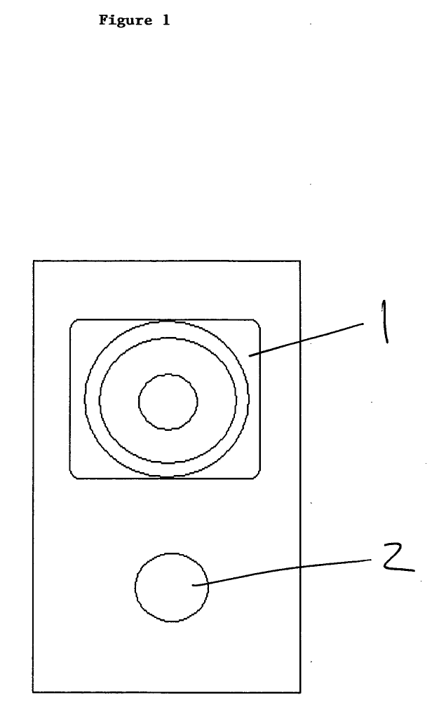

Front view of an embodiment of the claimed invention. The front view shows the front portion of the speaker 1 and one embodiment of a location for a vent 2.

FIG. 2

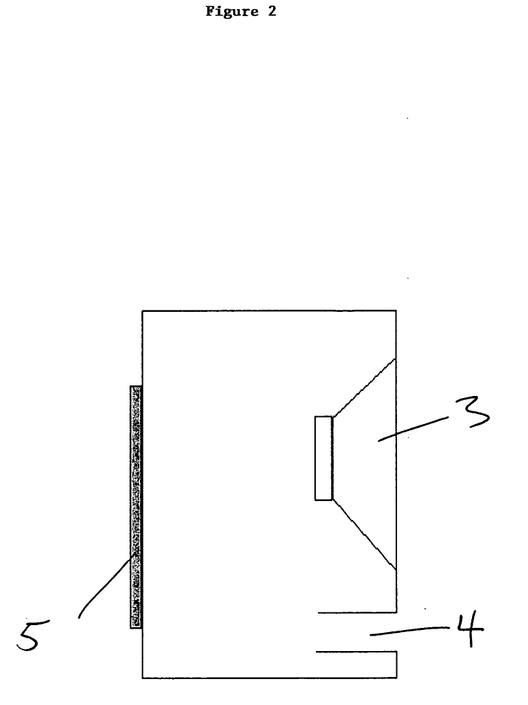

Side cutout view of an embodiment of the claimed invention. The side cutout view shows the side of the speaker 3 and side of the vent tube 4. Also shown is a strip of Velcro™ on the back surface of the case 5 to allow attachment to an article of luggage comprising a corresponding Velcro™ strip.

### DETAILED DESCRIPTION OF THE INVENTION

While this invention is susceptible of embodiment in many different forms, specific embodiments will herein be described in detail, with the understanding that the present disclosure is to be considered as an example of the principles of the invention and not intended to limit the invention to the specific embodiments shown and described.

This invention provides an enclosure for a speaker, wherein the enclosure comprises a means for attachment to an article of luggage, and wherein the enclosure is (i) composed of a suitable acoustic material and (ii) is flexible.

Suitable articles of luggage envisioned for the claimed invention include, but are not limited to backpacks, briefcases, messenger bags and purses.

In one embodiment, the suitable acoustic material is thermoformed. In another embodiment, the pieces of material are attached using adhesive or tensile methods.

Suitable acoustic materials are materials that are (i) stiff, i.e., the material is stable with variations in air pressure created by the speaker and (ii) well damped, i.e., if distorted by air pressure, the material is capable of returning to its original position without resonating. One skilled in the art would understand that a suitable acoustic material for the subject invention would be one stiff and well damped enough to produce a high quality audio output, yet flexible enough to resist damage (e.g., cracking of the enclosure). A flexible material can be, for example, a material capable of being slightly distorted by hand over a range of ambient temperatures. Examples of acceptable materials include, but are not limited to, ethylene vinyl acetate (EVA), polyethylene (PE) sheets, polyvinyl chloride (PVC) or polyethylene terephthalate (PET) blister or clamshell trays. In one embodiment, the enclosure consists of one type of material. In another embodiment, the enclosure consists of two or more types of material. For example, the enclosure can consist of (i) a rigid inner material so as to enhance audio quality and (ii) a flexible or padded outer material so as to protect the speaker and enclosure itself.

In one embodiment, the enclosure comprises ridges, buttresses, internal reinforcements or other structural properties and configurations capable of enhancing the acoustic output of the speaker. These characteristics can also serve to improve protection of the speaker and enclosure. In another embodiment, the enclosure comprises an opening, e.g., a vent, capable of enhancing the quality of the audio output of the speaker. The opening can be uncovered, or covered by a material that allows sound to pass through with little or no distortion or dampening of sound.

The size of the claimed invention will depend on the size of the speaker to be attached. In one embodiment, the enclosure is of a size so as to optimize the quality of the acoustic output of the speaker. One skilled in the art would be able to determine without undue experimentation the proper size of the enclosure for a particular speaker.

In one embodiment, the enclosure can be padded or insulated to protect the contents from shock, temperature, water, dust or other potentially damaging conditions.

The enclosure will also comprise a means for attaching itself to an article of luggage. The means for attachment being such so as to allow the enclosure to be manually removable from and manually attachable to the article of luggage. “Manually removable”, as used herein, means the enclosure can be detached and removed from the article of luggage without the use of any tool; similarly, “manually attachable”, as used herein, means the enclosure can be attached to the luggage without the use of any tool. Examples of such means of attachment include, but are not limited to, a Velcro™ strip, straps, a zipper and pockets.

This invention further provides a carrying case comprising the above-claimed speaker enclosure. In one embodiment, the carrying case comprises a manually removable enclosure for a speaker, which enclosure comprises a means for attachment to the carrying case and is (i) composed of a suitable acoustic material and (ii) is flexible. In another embodiment, the enclosure comprises a speaker. In another embodiment, the enclosure consists of two or more different materials. In one embodiment, the suitable acoustic material is ethylene vinyl acetate, polyethylene, polyvinyl chloride or polyethylene terephthalate. In one embodiment, the size of the carrying case is approximately the size of the speaker enclosure to be carried therein.

In one embodiment, the carrying case comprises ridges, buttresses, internal reinforcements or other structural properties and configurations capable of enhancing the acoustic output of the speaker. In another embodiment, the carrying case comprises ridges, buttresses, internal reinforcements or other structural properties and configurations capable of improving protection of the speaker and enclosure. In another embodiment, the carrying case further comprises an opening for enhancing the quality of the audio output of the speaker.

Accordingly, it is intended that the present invention embrace all such alternatives, modifications and variations that fall within the scope of the appended claims.

What is claimed is:

1. An enclosure for a speaker, wherein the enclosure comprises a means for attachment to an article of luggage, and wherein the enclosure is (i) composed of a suitable acoustic material and (ii) is flexible.

2. The enclosure of claim 1, wherein the enclosure consists of two or more different materials.

3. The enclosure of claim 1, wherein the suitable acoustic material is ethylene vinyl acetate, polyethylene, polyvinyl chloride or polyethylene terephthalate.

4. The enclosure of claim 1, wherein the enclosure comprises a speaker.

5. The enclosure of claim 1, wherein the enclosure comprises ridges, buttresses, internal reinforcements or other structural properties and configurations capable of enhancing the acoustic output of the speaker.

6. The enclosure of claim 1, wherein the enclosure comprises ridges, buttresses, internal reinforcements or other structural properties and configurations capable of improving protection of the speaker and enclosure.

7. The enclosure of claim 1, further comprising an opening for enhancing the quality of the audio output of the speaker.

8. A carrying case comprising a manually removable enclosure for a speaker, which enclosure comprises a means for attachment to the carrying case and is (i) composed of a suitable acoustic material and (ii) is flexible.

9. The carrying case of claim 8, wherein the enclosure comprises a speaker.

10. The carrying case of claim 8, wherein the enclosure consists of two or more different materials.

11. The carrying case of claim 8, wherein the suitable acoustic material is ethylene vinyl acetate, polyethylene, polyvinyl chloride or polyethylene terephthalate.

12. The carrying case of claim 8, wherein the carrying case comprises ridges, buttresses, internal reinforcements or other structural properties and configurations capable of enhancing the acoustic output of the speaker.

13. The carrying case of claim 8, wherein the carrying case comprises ridges, buttresses, internal reinforcements or other structural properties and configurations capable of improving protection of the speaker and enclosure.

14. The carrying case of claim 8, further comprising an opening for enhancing the quality of the audio output of the speaker.
